(19) United States
(12) Patent Application Publication
(10) Pub. No.: US 2007/0063777 A1
(43) Pub. Date: Mar. 22, 2007

(54) Electrostrictive devices

(76) Inventors: Mircea Capanu, St. Catharines (CA); Andrew Cervin-Lawry, Oaksville (CA); Thomas Bernacki, Hamilton (CA)

Correspondence Address: Joseph M. Sauer, Esq.;Jones Day, North Point, 901 Lakeside Avenue, Cleveland, OH, 44114, US

(21) Appl. No.: 11/508,465

(22) Filed: Aug. 23, 2006

Related U.S. Application Data
(60) Provisional application No. 60/711,933, filed on Aug. 26, 2005.

(51) Int. Cl. H03B 5/32

(52) U.S. Cl. 331/107 A

(57) ABSTRACT

A radio frequency (RF) device includes first and second electrodes and a polar dielectric made from a material having electrostrictive properties between the first and second electrodes. The polar dielectric and the first and second electrodes collectively form an active device having an operational frequency band. The RF device also includes one or more layers that affect the acoustic properties of the RF device such that the RF device absorbs RF energy at a frequency that is within the operational frequency band, whereby the RF device is an active device because the RF energy is absorbed at a frequency within the operational frequency band.

### CROSS-REFERENCE TO RELATED APPLICATION

This application claims priority from U.S. Provisional Application No. 60/711,933, titled “Electrostrictive Devices,” filed on Aug. 26, 2005, which is incorporated herein by reference in its entirety.

### FIELD

The technology described in this patent document relates generally to electrostrictive devices, and in particular, electrostrictive RF switches, oscillators, and filters that are DC-tunable and switchable.

### BACKGROUND AND SUMMARY

Using thin-film devices as capacitors is known in the art. Ferroelectric and paraelectric capacitors have potential for use as decoupling or voltage-tunable capacitors (varactors) in RF systems. Some benefits of ferroelectric and paraelectric capacitors are small size, integration of different values and functions of capacitors, and low cost. It would be beneficial to use these capacitors as active devices for resonators, switches, filters and reference circuit oscillators at GHz frequencies.

A radio frequency (RF) device includes first and second electrodes, and a polar dielectric made from a material having electrostrictive properties. The polar dielectric is between the first and second electrode. An active device is formed from the polar dielectric and the first and second electrode, and the active device has an operational frequency band. The device also has one or more layers that affect the acoustic properties of the device so that the capacitor absorbs RF energy at a frequency within the operational frequency band. The RF device is an active device because the RF energy is absorbed at a frequency within the operational frequency band.

A method of manufacturing an RF device includes fabricating an active device structure that includes a polar dielectric material made from a material having electrostrictive properties. The active device structure has an operational frequency band. The acoustic properties of the capacitor structure are modified such that the capacitor material absorbs RF energy at a frequency that is within the operational frequency band. The RF device is an active device because the RF energy is absorbed at a frequency within the operational frequency band.

### BRIEF DESCRIPTION OF THE DRAWINGS

FIGS. 1A and 1B depict a typical thin-film capacitor integrated circuit.

FIG. 2 is an example thin-film capacitor having a cavity that is fabricated in the substrate layer to create a void under the capacitor.

FIG. 3 is an example thin-film capacitor having a cavity that is fabricated in the substrate and insulating layers to create a void under the capacitor.

FIG. 4 is another example thin-film capacitor having a cavity that is fabricated in the substrate layer to create a void under the capacitor.

FIG. 5 is another example thin-film capacitor having a cavity that is fabricated in the substrate and insulating layers to create a void under the capacitor.

FIG. 6 is an example thin-film capacitor that includes a multi-layer acoustic reflector or absorber.

FIG. 7A is an example thin-film capacitor in which the substrate layer is completely or partially removed to create a void under the capacitor.

FIG. 7B is an example thin-film capacitor in which the substrate layer is completely or partially removed and that includes a cavity fabricated in a carrier substrate above the capacitor.

FIG. 8 is an example thin-film capacitor in which the substrate layer is completely or partially removed that includes a multi-layer acoustic reflector or absorber fabricated in the carrier substrate above the capacitor.

FIG. 9 is an example thin-film capacitor in which a cavity is fabricated between the capacitor and the substrate layer.

FIG. 10 is an example thin-film capacitor that uses a thin top electrode and a thin interconnect metallization to create a void above the capacitor.

FIG. 11 is an example thin-film capacitor that includes a thin single-layer top electrode.

FIG. 12 is a flow diagram illustrating an example method for fabricating a thin-film capacitor integrated circuit.

FIG. 13 is a flow diagram illustrating another example method for fabricating a thin-film capacitor integrated circuit.

FIG. 14 is a flow diagram illustrating a third example method for fabricating a thin-film capacitor integrated circuit.

FIG. 15 is a flow diagram illustrating a fourth example method for fabricating a thin-film capacitor integrated circuit.

FIG. 16 is a example of a physical representation and a circuit diagram of a resonator made from a thin-film capacitor.

FIG. 17 is an example ladder configuration of a thin-film capacitor configured to provide a filter characteristic.

### DETAILED DESCRIPTION

FIG. 1 depicts a typical thin-film capacitor integrated circuit. The upper portion of FIG. 1 depicts a cross-sectional diagram of the capacitor structure, and the lower portion of FIG. 1 depicts a top view showing the connections between the capacitor electrodes and an interconnect layer. With reference to the cross-section diagram shown in FIG. 1, the capacitor structure includes two conducting electrodes 10 that are separated by a dielectric layer 12. The conducting electrodes 10 may be, for example, fabricated using platinum or a platinum alloy. The dielectric layer 12 is fabricated using a electrostrictive dielectric material, such as Barium Strontium Titanate (BST). The capacitor is fabricated on a substrate material 14 coated with an insulating layer 16 and an etch-resistant insulating layer 18. The substrate 14 may be, for example, Si, Al₂O₃, Sapphire, or some other type of insulating, semi-insulating or semiconducting material. The insulating layer 16 may be SiO₂, and the etch-resistant insulating layer may be Si₃N₄. However, other materials with similar functionality may be also used. The conducting interconnect layer 20 may be used to electrically connect the capacitor electrodes to other circuitry, either within the integrated circuit (IC) package or to the external circuitry via the bump pads 22.

A common problem associated with thin-film capacitors made with electrostrictive dielectric materials, as shown in FIG. 1, are their electromechanical coupling (kₜ) and quality factor (Q) via electrostrictive effect that generates electric resonance, particularly in the 0.1 to 30 GHz range. These resonant frequencies and their associated kₜ and quality factors Q are the fundamental parameters that characterize electrostrictive resonance, and are directly related to the changes of the length and crystal lattice to even powers of electric polarization.

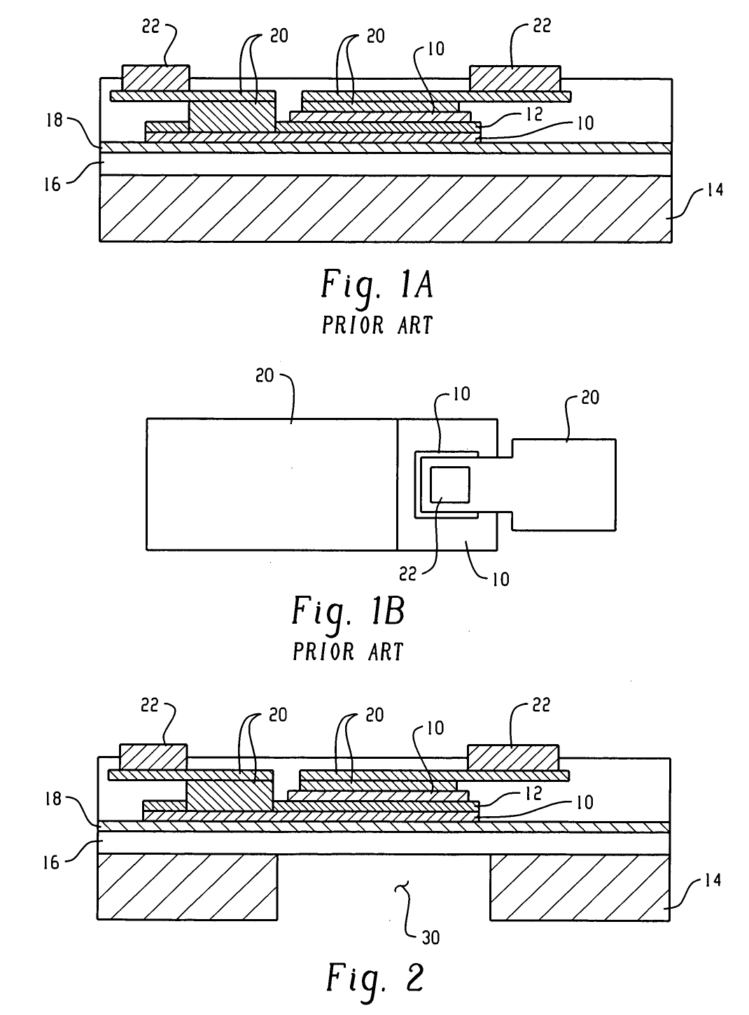

The examples described below with reference to FIGS. 2-15 provide a method for fabricating thin-film capacitors from electrostrictive dielectric materials, while maximizing the electromechanical Q of the resonant peaks at high frequencies, particularly in the 0.1 to 30 GHz frequency range under an applied electric field in the range of about 0.1 megavolts/cm (MV/cm) to about 10 (MV/cm). This result is achieved by modifying the structure of the capacitor to change the acoustic reflections at the interface of electrodes or other layers of the capacitor, such that the capacitor dielectric absorbs RF energy at the certain desired frequency required for the particular application. The cause of the RF energy conversion into acoustic wave energy and vice versa is the electrostrictive resonance. When a ferroelectric material is voltage biased, for example to tune the dielectric constant, the crystal lattice of the grains in the film are distorted. A variable electric field (from the RF signal) modulates this distortion and when the RF frequency matches the acoustic resonance of the structure, the RF energy is almost fully converted (conversion given by kₜ and Q) into acoustic energy. For example, the capacitor structures described below are modified to increase the Q at which the resonance is reinforced, resulting in capacitors having highest RF energy conversion and high Q values at resonant frequency (e.g., throughout the 0.1 to 30 GHz frequency band under voltage biases between 0.1 MV/cm to 10 MV/cm). These capacitors can be either single devices or integrated into a circuit on the substrate with other components such as other capacitors, resistors and/or inductors.

FIG. 2 is an example of a thin-film capacitor in which a cavity 30 is fabricated in the substrate layer 14 to create a void under the capacitor structure. The void under the capacitor structure serves as an acoustic reflector, which raises the Q of electrostrictive resonance of the capacitor 10, 12. The cavity 30 may be created by selectively removing the substrate 14, for example by laser drilling, ultrasonic milling (e.g., for ceramic substrates), deep RIE, wet anisotropic etching (e.g., on <100> or <110> oriented silicon), or other fabrication techniques.

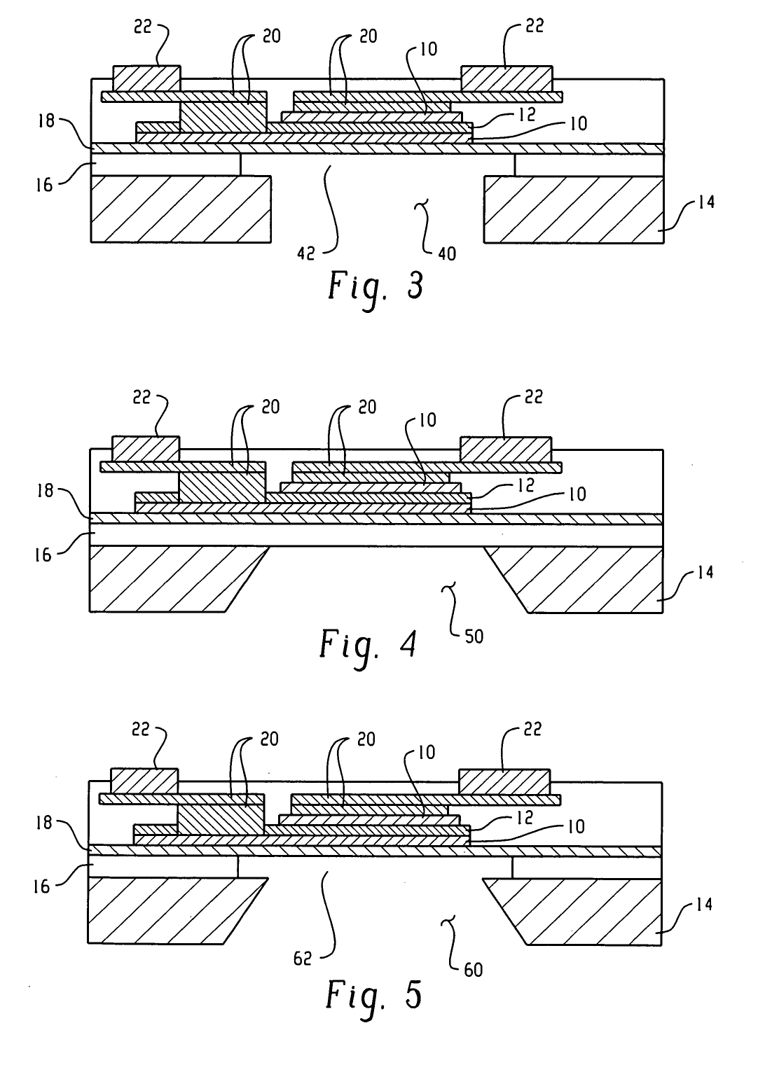

FIG. 3 is an example of a thin-film capacitor in which a cavity 40 is fabricated in the substrate 14 and insulating 16 layers to create a void under the capacitor structure. In this example the insulating layer is etched after the substrate layer. The insulating layer may be etched for example, using a wet etch based on hydrofluoric acid, a dry RIE etch, or some other means. Removing the insulating layer 16 creates a thinner acoustic layer between the capacitor structure 10, 12 and the void 40, thus further increasing the electrostrictive resonance Q of the capacitor compared to the example of FIG. 1.

FIG. 4 is another example of a thin-film capacitor in which a cavity 50 is fabricated in the substrate layer 14 to create a void under the capacitor structure.

FIG. 5 is another example of a thin-film capacitor in which a cavity 60, 62 is fabricated in the substrate 14 and insulating 16 layers to create a void under the capacitor structure. The thin-film capacitors shown in FIGS. 4 and 5 are similar to the examples of FIGS. 2 and 3 respectively, except that the substrate layer 14 is etched using an anisotropic backside etch. Anisotropic etching may be used, for example, in the case of a <100> Silicon substrate.

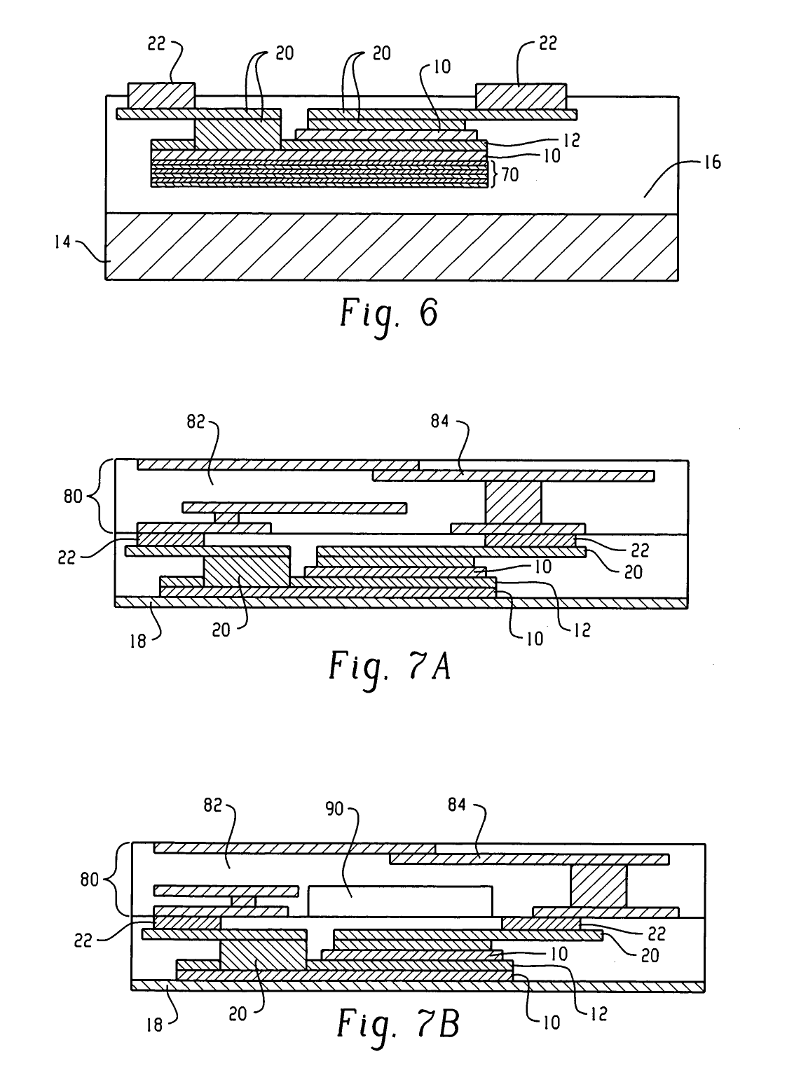

FIG. 6 is an example of a thin-film capacitor that includes a multi-layer acoustic reflector 70. In this example, the multi-layer acoustic reflector 70 is fabricated between the capacitor structure 10, 12 and the substrate layer 14. The multi-layer reflector or absorber includes two or more layers of alternating materials of different acoustic properties, which can be selected to reflect the acoustic waves. The materials used to fabricate the layers of the acoustic reflector 70 and the thickness of the layers 70 may be selected to reflect the acoustic wave at desired frequencies in order to maximize electrostrictive resonance Q of the capacitor 10, 12.

FIG. 7A is an example of a thin-film capacitor in which the substrate layer is completely or partially removed to create a void under the capacitor structure. In this example, the capacitor is bonded to a carrier substrate 80, using for example, flip-chip bonding methods. The carrier substrate 80 includes a substrate material 82, and conducting layers 84 which provide connections to the bonding pads 22 on thin-film capacitor IC. In other examples, the carrier substrate may also include additional layers, including for example active and/or passive thin-film components. After the thin-film capacitor is bonded to the carrier substrate 80, the substrate layer of the thin-film capacitor may be removed, leaving only the thin insulating layer 18 between the capacitor structure 10, 12 and an air void. In this manner, the air void under the capacitor structure 10, 12, serves as an acoustic reflector, which raises the electrostrictive resonance Q of the capacitor 10, 12. Moreover, the carrier substrate 80 provides the necessary physical support to maintain the structural integrity of the thin-film capacitor after the substrate has been completely or partially removed. The thin-film capacitor substrate may be removed for example, using either mechanical or chemical methods.

FIG. 7B is another example of a thin-film capacitor in which the substrate layer is completely or partially removed that includes a cavity fabricated in a carrier substrate 80 above the capacitor structure. This example is similar to the capacitor of FIG. 7A, with the addition of the cavity 90 in the carrier substrate 80. The cavity 90 above the capacitor structure 10, 12 forms an acoustic reflector, which further raises the electrostrictive resonance Q of the capacitor 10, 12.

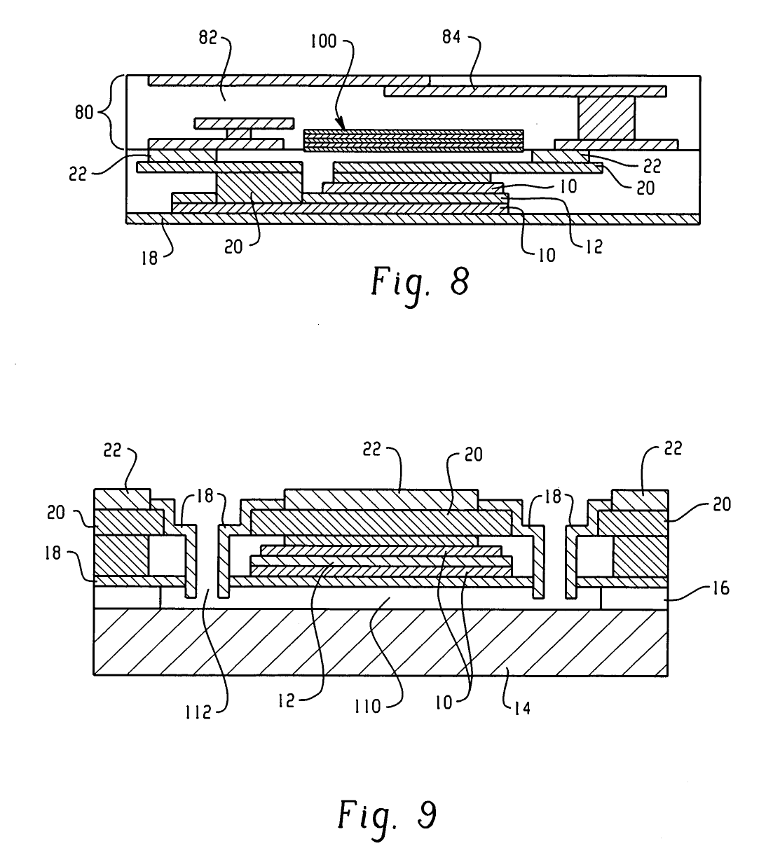

FIG. 8 is another example of a thin-film capacitor in which the substrate layer is completely or partially removed that includes a multi-layer acoustic reflector 100 fabricated in the carrier substrate 80 above the capacitor structure. The multi-layer reflector or absorber 100 includes two or more layers of alternating materials of different acoustic properties, which can be selected such that to reflect the acoustic waves. The air void under the capacitor structure 10, 12, which is created by completely or partially removing the substrate, serves as an acoustic reflector and combines with the multi-layer reflector or absorber 100 to raise the electrostrictive resonance frequency of the capacitor 10, 12. The materials used to fabricate the layers of the acoustic reflector or absorber 100 and the thickness of the layers 100 may be selected to reflect the acoustic wave at desired frequencies in order to maximize Q of the electrostrictive resonance of the capacitor 10, 12.

FIG. 9 is an example of a thin-film capacitor in which a cavity 110 is fabricated between the capacitor structure 10, 12 and the substrate layer 14. The cavity 110 serves as an acoustic reflector, which maximizes Q and kₜ of the electrostrictive resonance of the capacitor 10, 12. The cavity 110 may be fabricated by etching a portion of the insulating layer 16 through front-side access holes 112. The access holes 112 may, for example, be etched through the interlayer dielectric, lower electrode material and the underlying etch-resistant insulating layer to give access to the etchable insulating layer. The access holes 112 may then be lined with an etch-resistant insulating layer 18 to prevent damage to the capacitor structure 10, 12 and conducting layers 20. The cavity 110 may be formed by wet etching the insulating layer 16 through the access holes 112.

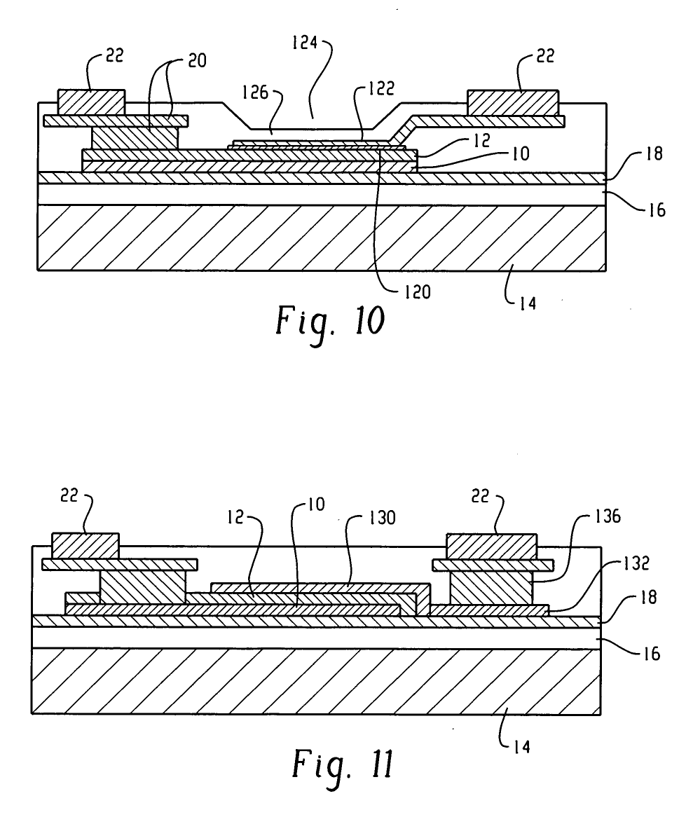

FIG. 10 is an example of a thin-film capacitor that uses a thin top electrode 120 and a thin interconnect metallization 122 to create a void 124 above the capacitor structure. The void 124 above the capacitor structure serves as an acoustic reflector, which maximizes Q of the electrostrictive resonance of the capacitor 10, 12, 120. The void 124 is created by fabricating the top electrode 120 of the capacitor and the attached interconnect metallization 122 from thin conductive layers and by minimizing the amount of insulating material 126 between the top capacitor electrode 120 and the air medium 124.

FIG. 11 is an example of a thin-film capacitor that includes a thin single-layer top electrode 130. In this example, the top electrode 130 of the capacitor includes an extended portion 132 that extends horizontally away from the capacitor in order to provide an electrical connection between the top electrode 130 to the interconnect metallization 136. The extended portion 132 of the top electrode 130 enables the interconnect metallization 136 to be horizontally offset from the top electrode 130, thus minimizing the thickness of material between the top electrode 130 and the air medium above the capacitor structure. In this manner, the air medium above the capacitor acts as an acoustic reflector, which maximizes Q of the electrostrictive resonance of the capacitor 10, 12, 130.

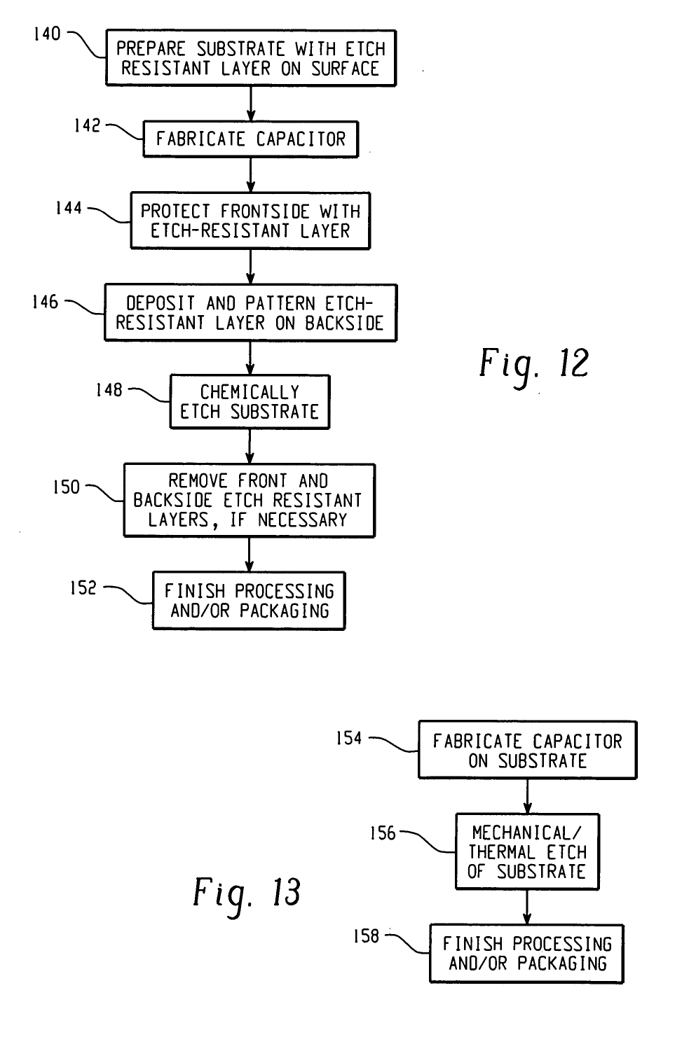

FIG. 12 is a flow diagram illustrating an example method for fabricating a thin-film capacitor integrated circuit. At step 140, a substrate layer is prepared with an etch-resistant layer on the surface to protect the capacitor structure and to act as an etch-stop for backside etching. The capacitor is fabricated on the substrate using conventional fabrication techniques at step 142. At step 144, the front side of the capacitor is protected with an etch-resistant layer, and another etch-resistant layer is deposited and patterned on the backside at step 146. At step 148, the substrate layer is completely or partially released using wet or dry chemical etching or a combination of both. Either a timed etch or the etch-resistant layer may be used to terminate the chemical etch. Once the substrate is released, the front and backside etch-resistant layers may be removed at step 150, and any additional fabrication and/or packaging processing are performed at step 152.

FIG. 13 is a flow diagram illustrating another example method for fabricating a thin-film capacitor integrated circuit. At step 154, a capacitor structure is fabricated on a substrate material using conventional fabrication techniques. Substrate material is then removed from the back to a pre-determined depth at step 156, stopping short of removing capacitor material. The substrate material may, for example, be removed using a laser, abrasive chemicals, ultrasonic milling and/or other mechanical or thermal means. Any additional fabrication and/or packaging processes may then be performed at step 158.

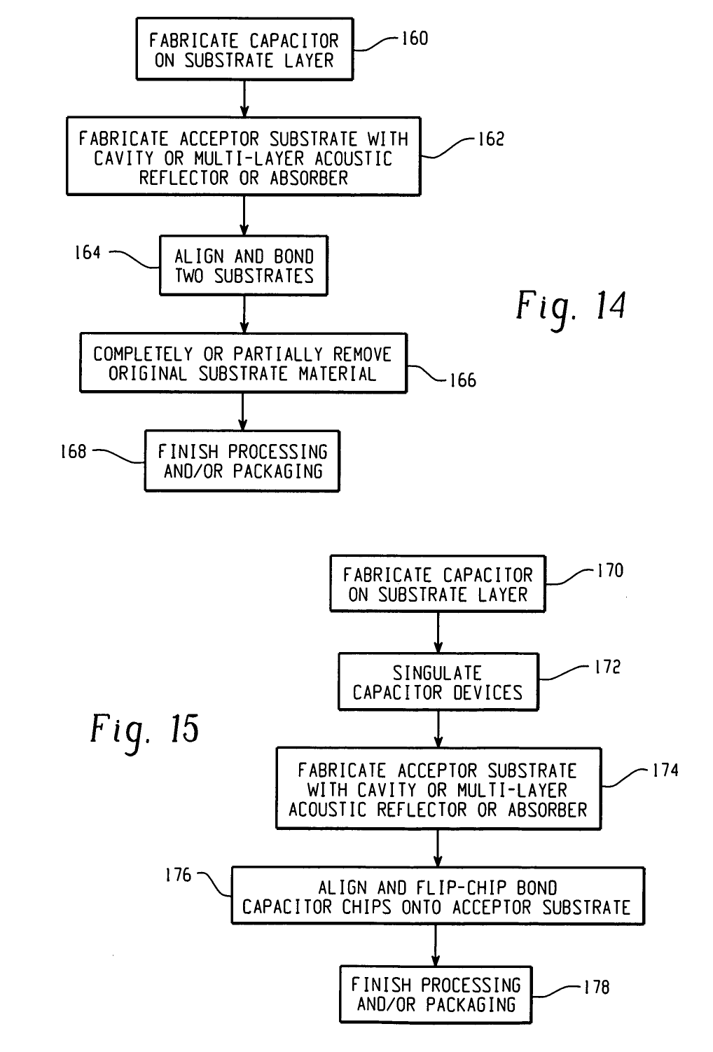

FIG. 14 is a flow diagram illustrating a third example method for fabricating a thin-film capacitor integrated circuit. At step 160, the capacitor structure is fabricated on a substrate material using conventional fabrication techniques. An acceptor substrate is then fabricated at step 162 that includes one or more cavities or multi-layer acoustic reflector or absorber structures (e.g., the carrier substrate 80 in FIGS. 7A, 7B and 8). At step 164, the acceptor substrate and the capacitor are aligned and bonded, for example using flip-chip bonding techniques. The original substrate is then completely or partially removed from the backside of the capacitor at step 166. The substrate may, for example, be removed using mechanical or chemical methods. Any additional fabrication and/or packaging processing may then be performed at step 168. The additional fabrication steps may include etching contact holes in the insulating layer on the backside and adding metal to reduce the series resistance of the capacitor.

FIG. 15 is a flow diagram illustrating a fourth example method for fabricating a thin-film capacitor integrated circuit. At step 170 the capacitor structure is fabricated on a substrate material using conventional fabrication techniques. Capacitor devices are then singulated at step 172. An acceptor substrate is fabricated at step 174 that includes one or more cavities or multi-layer acoustic reflectors or absorber structures (e.g., the carrier substrate 80 in FIGS. 7A, 7B and 8). At step 176, the acceptor substrate and the singulated capacitor are aligned and bonded, for example using flip-chip bonding techniques. Any additional fabrication and/or packaging processing may then be performed at step 178. The additional fabrication steps may include etching contact holes in the insulating layer on the backside and adding metal to reduce the series resistance of the capacitor.

When electrostrictive films such as Barium Strontium Titanate (BST) (BaₓSr_{y}; TiO3) are used in the thin-film capacitor structures discussed above, the capacitors can operate as active RF devices such as RF switches, oscillators and filters. Applicable frequency ranges for these devices may vary from 0.8 GHz to 30 GHz.

At zero bias and at room temperature, BST and other ferroelectric films do not have piezoelectric properties. However, they do have an electrostrictive property and gain piezoelectricity under a non-zero electric field (DC bias), known as the electrostrictive effect. The electrostrictive effect may lead to high losses at specific frequencies that are determined by the device's structure. By creating a device with the properties discussed above, the resonating structure can function as a frequency reference, as a band pass filter, or as an RF switch.

When DC bias is zero, no resonance occurs and the device behaves like a passive capacitor and no piezoelectric behavior occurs. Therefore, all active features of the device are turned off. If nonzero DC bias is applied, the RF signal has a resonance peak at the electrostrictive resonance. This occurs when the RF power is converted into the acoustic vibration, and vice versa via the electrostrictive (piezoelectric like) effect. Therefore, by applying a nonzero DC bias, BST capacitors can be used as any other piezoelectric resonators.

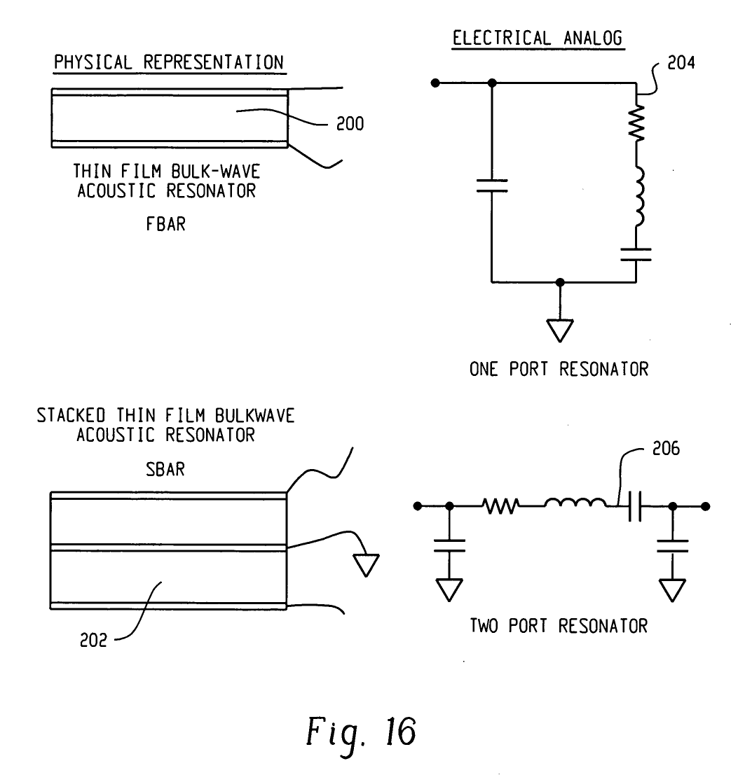

As shown in FIG. 16, a single resonator may be used for a reference circuit oscillator 200, or multiple resonators may be stacked to form multi-port resonators 202. At zero DC bias, if the capacitance of the capacitor is selected such that it provides a high impedance to the particular RF frequency, then the circuits of FIG. 16 provide a first switched state. In the presence of a DC bias, however, the electrostrictive characteristic of the BST material causes the circuits to provide a second switched state, as indicated by the activated RLC circuitry 204, 206. The resonance frequency may be selected by the thickness of the electrostrictive material, such as BST layers and the thickness of the coupling electrodes, such as platinum.

A ferroelectric electrostrictive device can be configured to provide RF switch functionality when switching the DC bias ON or OFF. A near perfect insertion loss may be achieved, with minimum RF and DC power loss within a smaller circuit size. This type of switch may consume relatively low power and may further be very fast acting because the response of the ferroelectric lattice is on the order of nanoseconds.

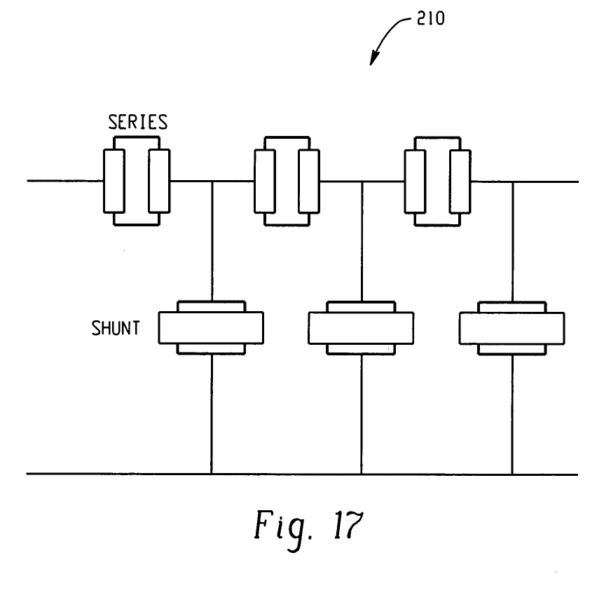

FIG. 17 provides an example ladder configuration 210 of BST devices configured to provide a filter characteristic. If the resonators discussed are connected into specific configurations such as the example in FIG. 17, the structure can function as a band-pass filter.

Electrostrictive based resonators and filters in the GHz frequency domain can enable switching and tuning capabilities together with piezoelectric behavior in a single device, eliminating the need of an additional RF switch and tunable passive capacitors. This facilitates a robust, well-established process for BST devices. Additionally, such BST devices have a high Q on the order of 1000-3000. The devices can provide for the further miniaturization of reference oscillators for FBAR resonators and crystal resonators. The devices can be integrated with other passive components, provide high RF power handling, and mitigate the need for an RF switch and mitigate associated RF signal losses.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

What is claimed is:

1. A radio frequency (RF) device, comprising:
first and second electrodes;
a polar dielectric made from a material having electrostrictive properties, the polar dielectric being interposed between the first and second electrodes, the polar dielectric and the first and second electrodes collectively forming an active device having an operational frequency band; and
one or more layers that affect the acoustic properties of the RF device such that the RF device absorbs RF energy at a frequency that is within the operational frequency band causing the RF device function as an active device.

2. The RF device of claim 1, wherein the absorption of RF energy causes the RF device to function as an RF switch.

3. The RF device of claim 1, wherein the absorption of RF energy causes the RF device to function as an RF oscillator.

4. The RF device of claim 1, wherein the absorption of RF energy causes the RF device to function as a band pass filter.

5. The RF device of claim 1, wherein the one or more layers include a substrate layer that defines a cavity, the cavity affecting the acoustic properties of the RF device such that the active device absorbs energy at the frequency that is within the operational frequency band.

6. The RF device of claim 1, wherein the one or more layers include an insulating layer that defines a cavity, the cavity affecting the acoustic properties of the RF device such that the polar dielectric absorbs RF energy at the frequency that is within the operational frequency band.

7. The RF device of claim 1, wherein the one or more layers include a substrate layer and an insulating layer that define a cavity, the cavity affecting the acoustic properties of the RF device such that the active device absorbs energy at the frequency within the operational frequency band.

8. The RF device of claim 1, wherein the one or more layers include an acoustic reflector that affects the acoustic properties of the RF device structure such that the polar dielectric absorbs RF energy at the frequency that is within the operational frequency band.

9. The RF device of claim 1, wherein the one or more layers include an acoustic absorber that affects the acoustic properties of the RF device such that the active device absorbs RF energy at the frequency within the operational frequency band.

10. The RF device of claim 8, wherein the acoustic reflector includes two or more layers with each layer of the acoustic reflector having a different acoustic impedance than adjacent layers of the acoustic reflector.

11. The RF device of claim 9, wherein the acoustic absorber includes two or more layers with each layer of the acoustic absorber having a different acoustic impedance than adjacent layers of the acoustic absorber.

12. The RF device of claim 1, wherein the one or more layers separate one of the first or second electrodes from an air void and the acoustic properties of the RF device are affected by a thickness of the one or more layers.

13. A method of manufacturing a radio frequency (RF) device, comprising:
fabricating an active device structure that includes a polar dielectric material made from a material having electrostrictive properties, the active device structure having an operational frequency band; and
modifying the acoustic properties of the active device structure such that the active device material absorbs RF energy at a frequency that is within the operational frequency band causing the RF device to function as an active device.

14. The method of claim 13, wherein the acoustic properties of the active device structure are modified by forming a cavity in one or more layers of the active device structure.

15. The method of claim 14, wherein the cavity is formed in an insulating layer.

16. The method of claim 14, wherein the cavity is formed in a substrate layer.

17. The method of claim 14, wherein the cavity is formed in an insulating layer and a substrate layer.

18. The method of claim 13, wherein the acoustic properties of the active device structure are modified by fabricating an acoustic reflector structure that includes two or more layers with each layer having a different acoustic impedance than adjacent layers.

19. The method of claim 13, wherein the acoustic properties of the active device structure are modified by fabricating an acoustic absorber structure that includes two or more layers with each layer having a different acoustic impedance than adjacent layers.

20. The method of claim 13, wherein the acoustic properties of the active device structure are modified by fabricating an insulating layer between the active device structure and an air void, wherein the acoustic properties of the active device structure are affected by a thickness of the insulating layer.

21. The method of claim 13, wherein the active device structure is fabricated on a substrate material and wherein the substrate material is subsequently removed tot modify the acoustic properties of the active device structure.

22. A radio frequency (RF) device, comprising:
first and second electrodes;
a polar dielectric made from a material having electrostrictive properties between the first and second electrodes, the polar dielectric and the first and second electrodes collectively forming an active device having an operational frequency band; and
means for affecting the acoustic properties of the RF device such that the active device absorbs RF energy at a frequency that is within the operational frequency band causing the RF device to function as an active device.
